(19) United States
(12) Patent Application Publication
(10) Pub. No.: US 2023/0225019 A1
(43) Pub. Date: Jul. 13, 2023

(54) HOB DEVICE

(71) Applicant: BSH Hausgeräte GmbH, Munich (DE)

(72) Inventors: Jorge Felices Betran, Huesca (ES); Alejandro del Cueto Belchi, Zaragoza (ES); Manuel Fernandez Martinez, Zaragoza (ES); Jose Miguel Gil Narvion, Zaragoza (ES); Pablo Jesus Hernandez Blasco, Zaragoza (ES); Eduardo Imaz Martinez, Tudela (Navarra) (ES); Paul Muresan, La Cartuja (ES); Jose Manuel Palacios Gasos, Zaragoza (ES); Alberto Perez Bosque, Zaragoza (ES); Pilar Perez Cabeza, Zaragoza (ES); Diego Puyal Puente, Zaragoza (ES); Javier Serrano Trullen, Zaragoza (ES)

(21) Appl. No.: 18/007,755

(22) PCT Filed: Jul. 7, 2021
(86) PCT No.: PCT/EP2021/068815

§ 371 Date: Dec. 2, 2022

(30) Foreign Application Priority Data
Jul. 17, 2020 (EP) 20382653.2

(51) Int. Cl. H05B 6/12; H05K 1/02; H05K 1/18

(52) U.S. Cl. CPC H05B 6/1209; H05K 1/028; H05K 1/18; H05K 1/0278; H05B 2213/05; H05K 2201/10151

(57) ABSTRACT

A hob apparatus includes a sensor unit configured to detect a sensor signal, an electronic signal processing unit configured to further process and/or analyze the sensor signal, and a printed circuit board, on which the sensor unit and the signal processing unit are arranged together.

The invention relates to a hob apparatus according to the preamble of claim 1.

Hobs with sensors, which are provided for example for detecting cookware or a temperature, are already known from the prior art. In some known embodiments a sensor is arranged on a printed circuit board. A signal detected by the sensor is forwarded from the printed circuit board by means of electrical contacts, for example by way of an edge connector, to a unit arranged away from the printed circuit board, for example a microprocessor, and then further processed and analyzed there.

The object of the invention is in particular, although without restriction thereto, to provide a generic apparatus with improved properties in respect of efficiency. The object is achieved according to the invention by the features of claim 1, while advantageous embodiments and developments of the invention will emerge from the subclaims.

The invention is based on a hob apparatus, in particular an induction hob apparatus, in particular with a heating unit, with a sensor unit that is in particular separate from the heating unit for detecting a sensor signal and with an electronic signal processing unit for further processing and/or analyzing the sensor signal.

It is proposed that the hob apparatus has a printed circuit board, on which the sensor unit and the signal processing unit are arranged together.

Such an embodiment advantageously provides a hob apparatus with improved properties in respect of efficiency. Because the sensor unit and the signal processing unit are arranged together on the printed circuit board, the sensor signal can advantageously be further processed and/or analyzed directly, with the result that an expensive edge connector with a plurality of electrical contacts, which would otherwise be required to forward the sensor signal, can be replaced by a simpler and less expensive connector, for example a Dbus2 type connector. This advantageously improves cost effectiveness, resulting in a particularly economical hob apparatus. It also advantageously allows efficiency to be increased in respect of further units of the hob apparatus and/or a hob that includes the hob apparatus. For example there is no need for a control unit microprocessor for activating the heating unit, as further processing and/or analysis of the sensor signal takes place directly in the signal processing unit, allowing a less powerful microprocessor to be used, thereby improving cost effectiveness further. Flexibility can also be advantageously increased, in that further sensor units are arranged together with further signal processing units on further printed circuit boards. This allows a modular structure to be simplified, flexibility to be increased in terms of the arrangement of the sensor units, for example in respect of different hob geometries, and operation of the sensor unit to be permitted independently of the heating unit.

A “hob apparatus”, in particular an “induction hob apparatus” refers to at least a part, in particular a sub-assembly, of a hob, in particular an induction hob. The hob apparatus could comprise for example at least one positioning plate, in particular at least one hob plate, which could be provided for example to receive cookware, in particular for the purpose of heating the cookware. The hob apparatus, in particular the induction hob apparatus, can also comprise the entire hob, in particular the entire induction hob. The hob apparatus is preferably configured as an induction hob apparatus. Alternatively however it would be conceivable for the hob apparatus to be part of a different hob type, for example a ceramic hob or the like.

A “heating unit” refers to a unit, which has at least one heating element, which in at least one operating state supplies energy to at least one object, for example cookware. The heating element of the heating unit could be configured for example as a heat radiating heating element for a ceramic hob and could supply energy in the form of heat radiation to the object in the operating state. The heating unit is preferably configured as an induction heating unit and has at least one heating element, which is configured as an induction heating element. The heating element configured as an induction heating element is provided to supply energy in the form of an electromagnetic alternating field, advantageously for the purpose of an inductive energy transfer, to the object in the operating state. The heating unit advantageously has at least two, particularly advantageously at least four, preferably at least eight and particularly preferably a plurality of heating elements. The heating elements of the heating unit can be arranged in a distributed manner, for example in the manner of a matrix.

A “sensor unit” refers to a unit, which has at least one sensor element for detecting the sensor signal, at least one electrical input for activation and at least one signal output for outputting the sensor signal to the signal processing unit. The sensor element and/or further sensor elements of the sensor unit could be configured for example as a capacitive sensor and/or a resistive sensor, for example a resistance thermometer (resistance temperature detector, RTD) and/or a temperature-dependent resistor (NTC thermistor) and/or an ultrasonic sensor and/or a piezoelectric sensor and/or a mechanical sensor. The at least one sensor element is preferably configured as an inductive sensor and comprises at least one induction coil. The sensor signal is preferably an electrical signal, which is present and/or drops and/or flows in the form of an electrical voltage and/or an electrical current, in particular in the form of an electrical AC voltage and/or an electrical alternating current, at the signal input and/or signal output of the sensor unit. The sensor unit can have a plurality of sensor elements, each being provided for detecting at least one sensor signal. The sensor unit advantageously has a number of sensor elements, corresponding at least to the number of heating elements in the heating unit. The sensor unit preferably has a larger number of sensor elements than the number of heating elements in the heating unit. The sensor signal is preferably provided for determining an operating state variable when the hob apparatus is in an operating state. The operating state variable could be, without restriction thereto, for example a temperature of a hob plate and/or a presence and/or a degree of cover of one or more heating elements of the heating unit and/or a shape and/or size and/or electrical and/or electromagnetic characteristic variable, for example an electrical resistance and/or an inductance of an object, in particular cookware, to which the heating unit supplies energy in the operating state.

A “signal processing unit” refers to an electronic unit, which comprises at least one electronic semiconductor element, preferably at least one semiconductor chip configured as a microcontroller (μController, μC, MCU) for further processing and/or analyzing the sensor signal. The further processing performed by means of the signal processing unit when the hob apparatus is in an operating state goes beyond simply forwarding the sensor signal to a further unit and comprises at least one conversion of the sensor signal from an analog signal form to a digital signal form. The analysis of the sensor signal preferably comprises the determination of the operating state variable. The signal processing unit can have at least one serial interface, which is provided for forwarding the sensor signal, in particular for subsequent analysis of the sensor signal, to further units, for example a control unit, in digital signal form.

“Provided” means specifically programmed, designed and/or equipped. That an object is provided for a specific function means that the object fulfils and/or executes said specific function in at least one application and/or operating state.

It is also proposed that the printed circuit board has at least one bending region. This advantageously improves the arrangement of the printed circuit board. It advantageously allows the printed circuit board to be arranged in a particularly compact and/or space-saving manner. A “bending region” refers to a sub-region that can be bent and/or is bent. Depending on the embodiment of the printed circuit board the bending region can be bent several times for assembly and then remain permanently bent or alternatively can be constantly bent.

The printed circuit board could be configured as a rigid printed circuit board. However in one advantageous embodiment it is proposed that at least parts of the printed circuit board are configured as flexible. Such an embodiment advantageously allows the arrangement of the printed circuit to be tailored particularly effectively to specific hob geometries, thereby improving the assembly process. The bending region can also advantageously be achieved with simple technical means. That “at least parts” of the printed circuit board “are configured as flexible means that the printed circuit board has at least one flexible sub-section or sub-region, in particular at least the bending region, which is able to be bent at least temporarily without suffering structural damage. The flexible sub-section and/or flexible sub-region of the partially flexible printed circuit board preferably has a modulus of elasticity of at least 3.0 GPa, particularly preferably at least 4.5 GPa.

It is also proposed that the printed circuit board is configured as a rigid-flexible printed circuit board. This advantageously provides a permanently bendable bending region and simplifies disassembly, for example for hob apparatus maintenance purposes. The printed board configured as a rigid-flexible printed circuit board could be made for example of a combination of flexible sub-layers, for example polyimide films, and rigid sub-layers, for example layers made of a composite of epoxy resin and glass fibers, in a pressing operation and have different regions of differing thickness and flexibility produced for example by deep milling.

In an alternative advantageous embodiment it is proposed that the printed circuit board is configured as a semi-flexible printed circuit board. This advantageously reduces cost, providing a particularly economical hob apparatus. The printed circuit board configured as a semi-flexible printed circuit board could be configured for example from a stack of layers, a number of what are known as prepregs, with at least one sub-region tapered down to a few layers, for example by milling or the use of pre-punched prepregs. The tapered sub-region could be provided with a permanently flexible coat of varnish and in particular form at least the bending region of the printed circuit board.

It is also proposed that a signal processing region of the printed circuit board is separated from a sensor region of the printed circuit board by the bending region. Such an embodiment advantageously allows a particularly expedient arrangement of the sensor unit and signal processing unit together on the printed circuit board. A “signal processing region” here is a sub-region of the printed circuit board, on which all the electronic components of the signal processing unit are arranged. A “sensor region” here is a sub-region of the printed circuit board, on which all the components of the sensor unit are arranged.

It is also proposed that the sensor region and the signal processing region are aligned at an angle to one another in an assembled state, in particular at least substantially perpendicular to one another. This advantageously improves the arrangement of the signal processing region and allows the signal processing unit to be effectively protected against thermal influences. The sensor region and the signal processing region are preferably aligned at an angle to one another in the assembled state such that the signal processing region is arranged in an edge region of the hob apparatus and/or a hob that includes the hob apparatus. When the signal processing region is arranged in the edge region, it is advantageously possible to protect electronic components of the signal processing unit effectively against thermal influences and therefore against damage due to excessively high temperatures.

In an alternative advantageous embodiment it is proposed that the sensor region and the signal processing region are aligned substantially parallel to one another in an assembled state. This provides a further embodiment with an advantageous arrangement for effectively protecting the signal processing region against thermal influences. The sensor region and the signal processing region are preferably aligned parallel to one another in the assembled state such that the signal processing region is arranged in a lower region of the hob apparatus and/or a hob that includes the hob apparatus. When the signal processing region is arranged in the lower region, it is advantageously possible to protect electronic components of the signal processing unit effectively against thermal influences and therefore against damage due to excessively high temperatures.

It is also proposed that the hob apparatus has a shielding element, with the sensor region and the signal processing region arranged on different sides of the shielding element in an assembled state. This advantageously improves the arrangement of the sensor unit and the signal processing unit. In addition to protection against thermal influences, it also advantageously allows protection of the electronic components of the signal processing unit arranged in the signal processing region against electromagnetic influences, thereby allowing particularly reliable operation of the signal processing unit. A “shielding element” here refers to an element which is provided to shield in particular electrical and/or electronic components of the hob apparatus and/or the hob that includes the hob apparatus that are arranged away from the shielding element, in particular below the heating unit of the hob apparatus and/or the hob that includes the hob apparatus, for example a control unit, against electromagnetic fields generated by at least the heating unit, in particular by at least an induction heating element of the heating unit, of the hob apparatus and/or the hob that includes the hob apparatus.

In the assembled state the bending region could be arranged bent on an outer edge of the shielding element such that the sensor region and the signal processing region are arranged on different sides of the shielding element. In one advantageous embodiment it is however proposed that the shielding element has an opening through which the bending region is passed in the assembled state. Such an embodiment advantageously allows particularly versatile arrangement of the printed circuit board. It advantageously also allows effective protection of the signal processing unit against thermal and/or electromagnetic influences, even if the printed circuit board is arranged in a central region below a hob plate of the hob apparatus and/or a hob that includes the hob apparatus, in that the shielding element has an opening in a central region, through which the bending region is passed in the assembled state.

It is also proposed that the signal processing region is at least substantially rigid. This advantageously improves the arrangement of electronic components of the signal processing unit in the signal processing region and optimizes the production and/or assembly process for the signal processing unit.

It is further proposed that the sensor region is at least substantially rigid. Such an embodiment advantageously optimizes the arrangement of components of the sensor unit and the production and/or assembly process for the sensor unit.

It is also proposed that the hob apparatus has at least one protection element arranged above the signal processing unit for protecting the signal processing unit against thermal influences. Such an embodiment advantageously allows the hob apparatus to have a particularly compact structure. The protection element advantageously allows the signal processing unit to be arranged in proximity to a hob plate of the hob apparatus and/or a hob that includes the hob apparatus with the signal processing unit, in particular temperature-sensitive electronic components of the signal processing unit, being effectively protected against thermal influences. Thermal influences can, without restriction thereto, be produced for example by heat conduction and/or convection and/or heat radiation from the heating unit and/or cookware or the like positioned above the heating unit. The protection element could, without restriction hereto, be configured for example from a thin, in particular transparent, layer made of glass fibers or a silica aerogel.

It is also proposed that the hob apparatus has a further sensor unit for detecting at least one further sensor signal, a further signal processing unit for further processing and/or analyzing the further sensor signal and a further printed circuit board, on which the further sensor unit and the further signal processing unit are arranged together. This advantageously increases the functional scope of the hob apparatus. The hob apparatus can have a plurality of further printed circuit boards, on each of which a further sensor unit and a further signal processing unit are arranged together. The further sensor unit and/or the further signal processing unit and/or the further printed circuit board can each have one or more features according to one of the embodiments described above in respect of the sensor unit and/or signal processing unit and/or printed circuit board. It is conceivable that the sensor signal and the further sensor signal are provided for determining different operating state variables. For example the sensor signal could be provided for determining a presence of and/or degree of cover by cookware positioned above the heating unit and the further sensor signal could be provided for determining a temperature. It is also conceivable that the sensor unit and the further sensor unit, the signal processing unit and the further signal processing unit and the printed circuit board and the further printed circuit board are configured in an at least substantially identical manner. For example the printed circuit board, on which the sensor unit and the signal processing unit are arranged together, could be arranged above a first heating element of the heating unit and could be provided for determining an operating state variable relating to the first heating element and the further printed circuit board, on which the further sensor unit and the further signal processing unit are arranged together, could be arranged above a second heating element of the heating unit and could be provided for determining an operating state variable relating to the second heating element.

The invention also relates to a hob, in particular an induction hob, having a hob apparatus according to one of the embodiments proposed above. Such a hob is characterized by its advantageous properties in respect of efficiency.

The hob apparatus here should not be restricted to the application and embodiment described above. In particular the hob apparatus can have a number of individual elements, components and units that is different from the number cited herein to comply with a mode of operation described herein.

Further advantages will emerge from the description of the drawing that follows. The drawing shows exemplary embodiments of the invention. The drawing, description and claims contain numerous features in combination. The person skilled in the art will expediently also consider the features individually and combine them in meaningful further combinations.

In the drawing:

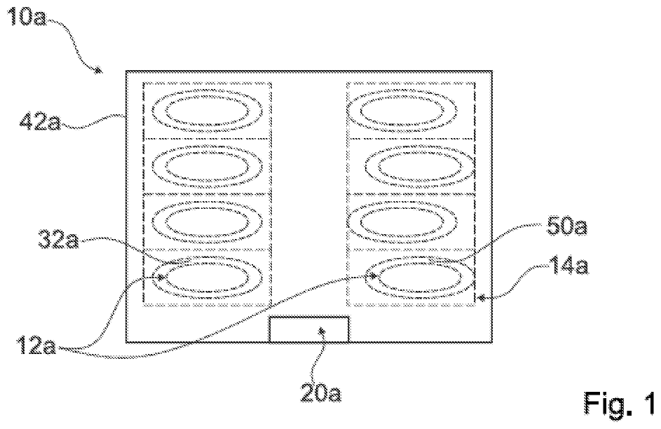

FIG. 1 shows a schematic top view of a hob with a hob apparatus,

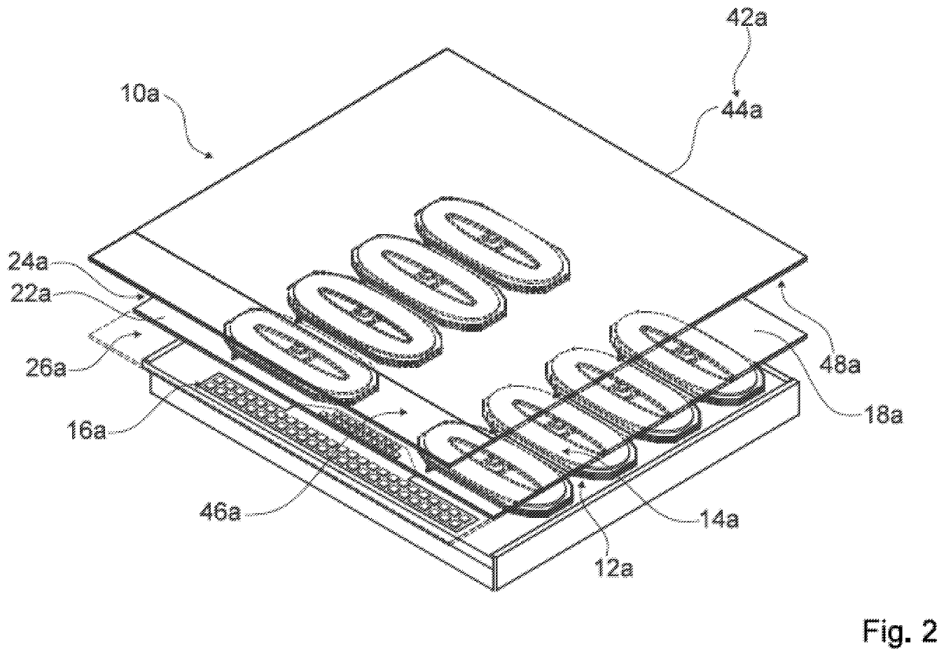

FIG. 2 shows a schematic exploded view of the hob apparatus with a sensor unit and a signal processing unit,

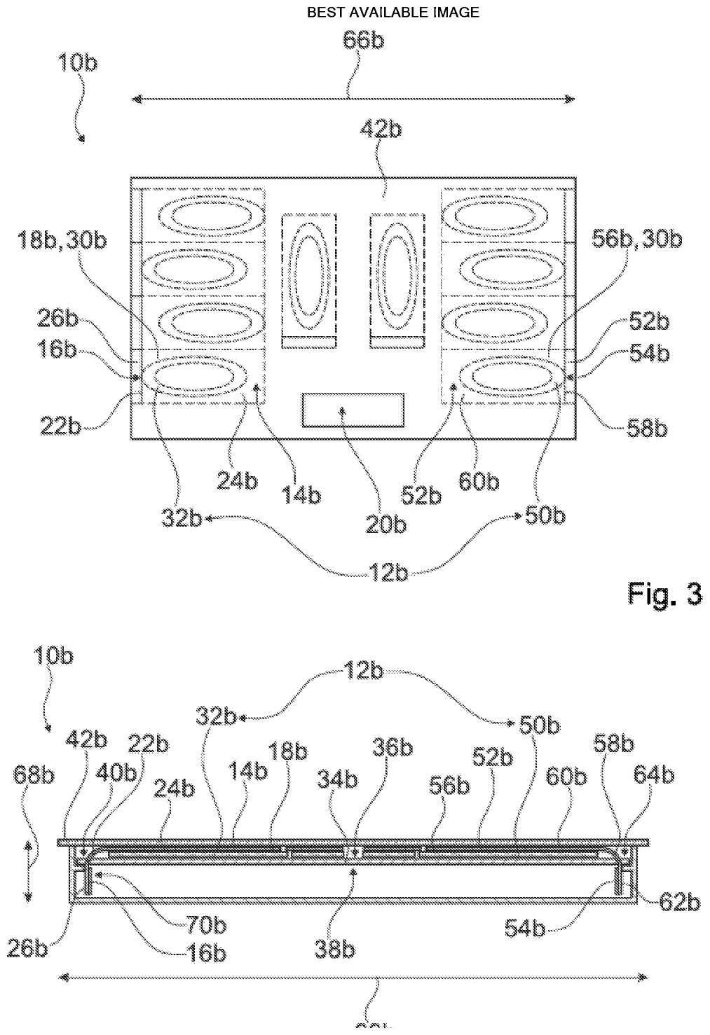

FIG. 3 shows a schematic top view of a further exemplary embodiment of a hob apparatus,

FIG. 4 shows a schematic sectional view of the exemplary embodiment of the hob apparatus from FIG. 3,

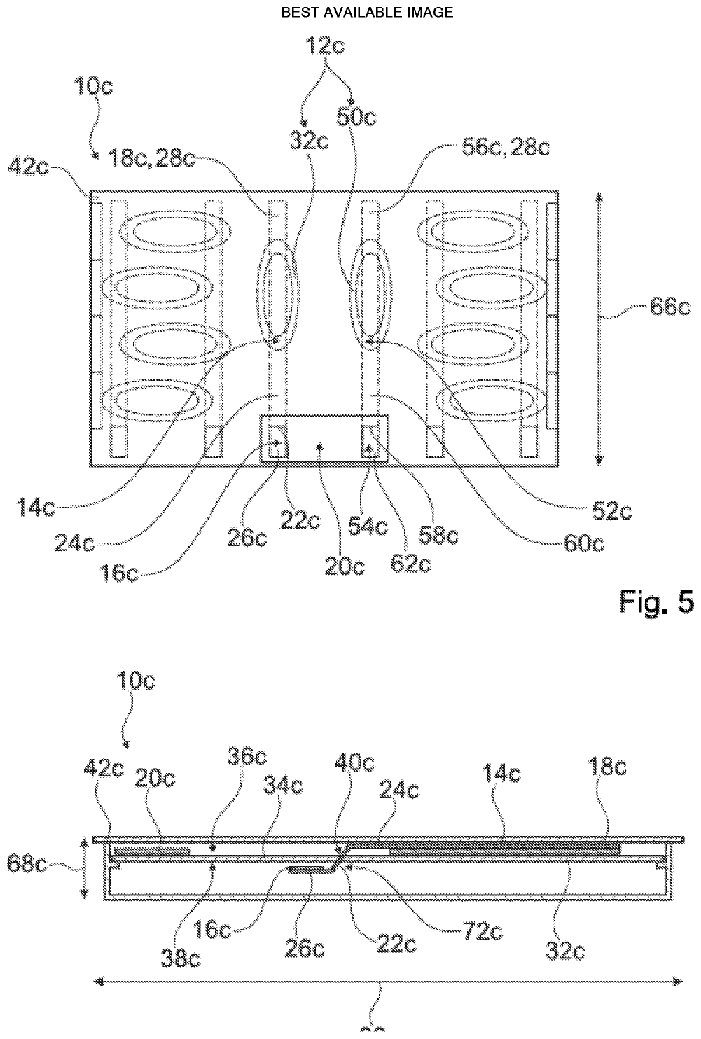

FIG. 5 shows a schematic top view of a further exemplary embodiment of a hob apparatus, and

FIG. 6 shows a schematic sectional view of the exemplary embodiment of the hob apparatus from FIG. 5.

FIG. 1 shows a schematic top view of a hob 42a. The hob 42a is configured as an induction hob. The hob 42a has a hob apparatus 10a. The hob apparatus 10a is configured as an induction hob apparatus. The hob comprises an operating unit 20a. The operating unit 20a is provided for a user to control the hob 42a.

The hob apparatus 10a comprises a heating unit 12a with a number of heating elements 32a and further heating elements 50a, each of which is configured as an inductor.

Where a number of objects is present only one is shown with a reference character in the figures.

The hob apparatus 10a comprises a sensor unit 14a. The sensor unit 14a is provided for detecting a sensor signal (not shown).

FIG. 2 shows a schematic exploded view of the hob apparatus 10a. The hob apparatus 10a comprises a signal processing unit 16a. The signal processing unit 16a is provided for further processing and/or analyzing the sensor signal. When the hob apparatus 10a is in an operating state, the signal processing unit 16a determines a presence of and/or degree of cover by cookware (not shown) positioned on a hob plate 44a of the hob 42a based on the sensor signal.

The hob apparatus 10a has a printed circuit board 18a. The sensor unit 14a and the signal processing unit 16a are arranged together on the printed circuit board 18a.

When the hob apparatus 10a is in the assembled state, the printed circuit board 18a is arranged above the heating unit 12a. In the assembled state the printed circuit board 18a is arranged below the hob plate 44a of the hob 42a.

The printed circuit board 18a has a bending region 22a. The printed circuit board 18a has a sensor region 24a. The sensor unit 14a is arranged in the sensor region 24a on the printed circuit board 18a. The printed circuit board 18a has a signal processing region 26a. The signal processing unit 16a is arranged in the signal processing region 26a on the printed circuit board 18a. The signal processing region 26a of the printed circuit board 18a is separated from the sensor region 24a of the printed circuit board 18a by the bending region 22a. At least parts of the printed circuit board 18a are configured as flexible. In the present exemplary embodiment the bending region 22a of the printed circuit board 18a is configured as flexible.

The sensor region 24a of the printed circuit board 18a is at least substantially rigid. The signal processing region 26a of the printed circuit board 18a is at least substantially rigid.

The hob apparatus 10a has a protection element 46a. The protection element 46a is provided for protecting the signal processing unit 16a against thermal influences. The protection element 46a is attached to a lower side 48a of the hob plate 44a. The protection element 46a is configured as a thin transparent layer made of a silica aerogel. In the assembled state the protection element 46a extends over the signal processing region 26a. When the hob apparatus 10a is in the operating state, the protection element protects the signal processing unit 16a against thermal influences, specifically temperature influences from the hob plate 44a.

FIGS. 3 to 6 show two further exemplary embodiments of the invention.

The descriptions that follow are restricted substantially to the differences between the exemplary embodiments, it being possible to refer to the description of the exemplary embodiment in FIGS. 1 to 2 for components, features and functions that remain the same. To distinguish between the exemplary embodiments the letter a in the reference characters of the exemplary embodiment in FIGS. 1 to 2 is replaced by the letters b and c in the reference characters of the exemplary embodiments in FIGS. 3 to 6. Reference can also be made in principle to the drawings and/or the description of the exemplary embodiment in FIGS. 1 to 2 for components of identical designation, in particular for components with identical reference characters.

FIG. 3 shows a schematic top view of a hob apparatus 10b. The hob apparatus 10b is part of a hob 42b configured as an induction hob and is configured as an induction hob apparatus. The hob apparatus 10b comprises a heating unit 12b with a number of heating elements 32b and a number of further heating elements 50b. The heating element 32b and the further heating elements 50b are each configured as inductors.

The hob apparatus 10b comprises a sensor unit 14b for detecting a sensor signal (not shown) and a signal processing unit 16b for further processing and/or analyzing the sensor signal. When the hob apparatus 10b is in an operating state, the signal processing unit 16b determines a presence of and/or degree of cover by cookware (not shown) positioned above the heating element 32b of the heating unit 12b based on the sensor signal.

The hob apparatus 10b comprises a printed circuit board 18b. The sensor unit 14b and the signal processing unit 16b are arranged together on the printed circuit board 18b. The printed circuit board 18b comprises a bending region 22b. At least parts of the printed circuit board 18b are configured as flexible. The printed circuit board 18b is configured as a semi-flexible printed circuit board 30b. The semi-flexible printed circuit board 30b can be bent several times for assembly. The bending region 22b is produced during assembly. When the hob apparatus 10b is in an assembled state, the bending region 22b is bent (see FIG. 4).

A signal processing region 26b of the printed circuit board 18b, on which the signal processing unit 16b is arranged, is separated from a sensor region 24b of the printed circuit board 18b, on which the sensor unit 14b is arranged, by the bending region 22b.

The hob apparatus 10b has a number of further sensor units 52b. The hob apparatus 10b has a number of further signal processing units 54b. The hob apparatus 10b has a number of further printed circuit boards 56b. The further sensor units 52b, the further signal processing units 54b and the further printed circuit boards 56b are configured in a substantially identical manner to one another, so the description that follows is restricted to one further sensor unit 52b, one further signal processing unit 54b and one further printed circuit board 56b.

The further sensor unit 52b is provided for detecting a further sensor signal (not shown). The further signal processing unit 54b is provided for further processing and/or analyzing the further sensor signal. The further sensor unit 52b and the further signal processing unit 54b are arranged together on the further printed circuit board 56b.

When the hob apparatus 10b is in the operating state, the further signal processing unit 54b determines a presence of and/or degree of cover by cookware (not shown) positioned above the further heating element 50b of the heating unit 12b based on the further sensor signal.

The further printed circuit board 56b has a further bending region 58b. A further signal processing region 62b of the further printed circuit board 56b, on which the further signal processing unit 54b is arranged, is separated from a further sensor region 60b of the further printed circuit board 58b, on which the further sensor unit 52b is arranged, by the further bending region 58b.

At least parts of the further printed circuit board 56b are configured as flexible. The further printed circuit board 56b is configured as a semi-flexible printed circuit board 30b. The further printed circuit board 56b configured as a semi-flexible printed circuit board 30b can be bent several times for assembly. The further bending region 58b is produced during assembly.

FIG. 4 shows a schematic sectional view of the hob apparatus 10b. The hob apparatus 10b has a shielding element 34b. The shielding element 34b is provided for shielding electromagnetic radiation radiated by the heating element 32b and/or the further heating element 50b in the operating state.

When the hob apparatus 10b is in the assembled state, the sensor region 24b and the signal processing region 26b are on different sides 36b, 38b of the shielding element 34b. In the assembled state the sensor region 24b is arranged on an upper side 36b of the shielding element. In the assembled state the signal processing region 26b is arranged on a lower side 38b of the shielding element 34b.

The shielding element 34b has an opening 40b. In the assembled state the bending region 22b of the printed circuit board 18b is passed through the opening 40b.

In the assembled state the sensor region 24b and the signal processing region 26b are aligned at an angle, specifically at least substantially perpendicular, to one another. In the assembled state the sensor region 24b is aligned substantially parallel to a horizontal extension 66b of the hob 42b. The signal processing region 26b is arranged in an edge region 70b of the hob 42b and aligned substantially parallel to a vertical extension 68b of the hob 42b. The signal processing unit 16b is protected against thermal and electromagnetic influences from the heating unit 12b on the signal processing region 26b of the printed circuit board 18b in the edge region 70b of the hob 42b.

The shielding element 34b has a further opening 64b. In the assembled state the further bending region 58b of the further printed circuit board 56b is passed through the further opening 64b. In the assembled state the further sensor region 60b is arranged on the upper side 36b of the shielding element 34b and the further signal processing region 62b on the lower side 38b of the shielding element 34b. In the assembled state the further sensor region 60b and the further signal processing region 62b are aligned at an angle, specifically at least substantially perpendicular, to one another.

FIG. 5 shows a schematic top view of a hob apparatus 10c. The hob apparatus 10c is part of a hob 42c configured as an induction hob and is configured as an induction hob apparatus. The hob apparatus 10c comprises a heating unit 12c with a number of heating elements 32c and with a number of further heating elements 50c. The heating elements 32c and the further heating elements 50c are each configured as inductors. The hob apparatus 10c comprises a sensor unit 14c for detecting a sensor signal (not shown) and a signal processing unit 16c for further processing and/or analyzing the sensor signal. The sensor unit 14c and the signal processing unit 16c are arranged together on a printed circuit board 18c of the hob apparatus 10c.

The printed circuit board 18c has a bending region 22c, which separates a sensor region 24c from a signal processing region 26c. At least parts of the printed circuit board 18c are configured as flexible. The printed circuit board 18c is configured as a rigid-flexible printed circuit board 28c.

The hob apparatus 10c has a number of further sensor units 52c for detecting further sensor signals and a number of further signal processing units 54c for further processing and/or analyzing the further sensor signals, these being arranged together on further printed circuit boards 56c of the hob apparatus 10c. The further sensor units 52c, the further signal processing units 54c and the further printed circuit boards 56c are configured in a substantially identical manner to one another, so the description that follows is restricted to one further sensor unit 52c, one further signal processing unit 54c and one further printed circuit board 56c.

When the hob apparatus 10c is in an operating state, the signal processing unit 16c uses the sensor signal and the further signal processing unit 54c uses the further sensor signal to determine a presence of and/or degree of cover of one or more of the heating elements 32b and/or the further heating elements 50c of the heating unit 12b by one or more items of cookware (not shown) positioned above.

FIG. 6 shows a schematic sectional view of the hob apparatus 10c. The hob apparatus 10c has a shielding element 34c. The shielding element 34c has an opening 40c. In the assembled state the bending region 22c of the printed circuit board 18c is passed through the opening 40c. In the assembled state the sensor region 24c is arranged on an upper side 36c of the shielding element. In the assembled state the signal processing region 26c is arranged on a lower side 38c of the shielding element 34c.

The sensor region 24c and the signal processing region 26c are aligned at least substantially parallel to one another in the assembled state. The sensor region 24c and the signal processing region 26c are each aligned substantially parallel to a horizontal extension 66c of the hob 42c. The signal processing unit 16c is protected against thermal and electromagnetic influences from the heating element 32c of the heating unit 12c on the signal processing region 26c of the printed circuit board 18c in a lower region 72c of the hob 42c.

### REFERENCE CHARACTERS

10 Hob apparatus
12 Heating unit
14 Sensor unit
16 Signal processing unit
18 Printed circuit board
20 Operating unit
22 Bending region
24 Sensor region
26 Signal processing region
28 Rigid-flexible printed circuit board
30 Semi-flexible printed circuit board
32 Heating element
34 Shielding element
36 Upper side
38 Lower side
40 Opening
42 Hob
44 Hob plate
46 Protection element
48 Lower side
50 Further heating element
52 Further sensor unit
54 Further signal processing unit
56 Further printed circuit board
58 Further bending region
60 Further sensor region
62 Further signal processing region
64 Further opening
66 Horizontal extension
68 Vertical extension
70 Edge region
72 Lower region

1-15. (canceled)

16. A hob apparatus, comprising:
a sensor unit configured to detect a sensor signal;
an electronic signal processing unit configured to further process and/or analyze the sensor signal; and
a printed circuit board, on which the sensor unit and the signal processing unit are arranged together.

17. The hob apparatus of claim 16, embodied as an induction hob apparatus.

18. The hob apparatus of claim 16, wherein the printed circuit board includes a bending region.

19. The hob apparatus of claim 16, wherein the printed circuit board includes a flexible part.

20. The hob apparatus of claim 16, wherein the printed circuit board is configured as a rigid-flexible printed circuit board.

21. The hob apparatus of claim 16, wherein the printed circuit board is configured as a semi-flexible printed circuit board.

22. The hob apparatus of claim 18, wherein the printed circuit board includes a signal processing region which is separated from a sensor region of the printed circuit board by the bending region.

23. The hob apparatus of claim 22, wherein the sensor region and the signal processing region are aligned at an angle to one another in an assembled state.

24. The hob apparatus of claim 22, wherein the sensor region and the signal processing region are aligned at least substantially perpendicular to one another in an assembled state.

25. The hob apparatus of claim 22, wherein the sensor region and the signal processing region are aligned at least substantially parallel to one another in an assembled state.

26. The hob apparatus of claim 22, further comprising a shielding element, wherein the sensor region and the signal processing region are arranged on different sides of the shielding element in an assembled state.

27. The hob apparatus of claim 26, wherein the shielding element has an opening for passage of the bending region in the assembled state.

28. The hob apparatus of claim 22, wherein the signal processing region is at least substantially rigid.

29. The hob apparatus of claim 16, wherein the sensor region is at least substantially rigid.

30. The hob apparatus of claim 16, further comprising a protection element arranged above the signal processing unit for protecting the signal processing unit against thermal influence.

31. The hob apparatus of claim 16, further comprising:
a further sensor unit configured to detect a further sensor signal;
a further signal processing unit configured to further process and/or analyze the further sensor signal; and
a further printed circuit board, on which the further sensor unit and the further signal processing unit are arranged together.

32. A hob, comprising a hob apparatus, said hob apparatus comprising a sensor unit configured to detect a sensor signal, an electronic signal processing unit configured to further process and/or analyze the sensor signal, and a printed circuit board, on which the sensor unit and the signal processing unit are arranged together.

33. The hob of claim 32, embodied as an induction hob.
